(19) United States
(12) Patent Application Publication
(10) Pub. No.: US 2014/0124753 A1
(43) Pub. Date: May 8, 2014

(54) ORGANIC LIGHT-EMITTING DIODE

(71) Applicant: Samsung Display Co., Ltd., Yongin City (KR)

(72) Inventors: Hyun-Shik LEE, Yongin-City (KR); Kyu-Seok KIM, Yongin-City (KR)

(73) Assignee: Samsung Display Co., Ltd., Yongin City (KR)

(21) Appl. No.: 13/947,955

(22) Filed: Jul. 22, 2013

(30) Foreign Application Priority Data
Nov. 7, 2012 (KR) 10-2012-0125701

(51) Int. Cl. H01L 51/52

(52) U.S. Cl. CPC H01L 51/52
USPC 257/40

(57) ABSTRACT

An organic light-emitting diode is provided which is capable of preventing screen stain occurring when the organic light-emitting diode is driven at low gradation and/or low brightness.

### CROSS-REFERENCE TO RELATED APPLICATIONS

This application claims the benefit of Korean Patent Application No. 10-2012-0125701, filed on Nov. 7, 2012, in the Korean Intellectual Property Office, the disclosure of which is incorporated herein in its entirety by reference.

### BACKGROUND

1. Field

Organic light-emitting diodes are disclosed.

2. Description of the Related Technology

Organic light-emitting diodes (OLEDs), which are self-emitting diodes, have advantages such as wide viewing angles, excellent contrast, quick response, high brightness, excellent driving voltage characteristics, and can provide multicolored images.

A typical OLED has a structure including a substrate, and an anode, a hole transport layer (HTL), an emission layer (EML), an electron transport layer (ETL), and a cathode which are sequentially stacked on the substrate. The HTL, the EML, and the ETL are organic thin films formed of organic compounds.

An operating principle of an OLED having the above-described structure is as follows.

Holes injected from the anode move to the EML via the HTL, and electrons injected from the cathode move to the EML via the ETL. The holes and electrons (carriers) recombine in the organic EML to generate excitons. When the excitons drop from an excited state to a ground state, light is emitted.

### SUMMARY

By controlling a doping region of a dopant in an emission layer of an organic light-emitting diode, screen stain occurring when the organic light-emitting diode is driven at low gradation and/or low brightness is prevented.

According to one aspect, an organic light-emitting diode comprising: a substrate; a first electrode on the substrate; a second electrode facing the first electrode; an emission layer that is interposed between the first electrode and the second electrode and comprises a host and a dopant; a hole transport region interposed between the first electrode and the emission layer; and an electron transport region interposed between the emission layer and the second electrode, wherein the emission layer comprises a non-doping layer that comprises the host and does not comprise the dopant and a doping layer that comprises the host and the dopant, wherein the non-doping layer and the doping layer are sequentially stacked from the hole transport region, are provided.

### BRIEF DESCRIPTION OF THE DRAWINGS

The above and other features and advantages of the present embodiments will become more apparent by describing in detail example embodiments thereof with reference to the attached drawings in which:

FIG. 1 is a schematic view of the structure of an organic light-emitting diode according to an embodiment; and

FIG. 2 shows gradation-brightness efficiency graphs of organic light-emitting diodes 1 to 3.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list.

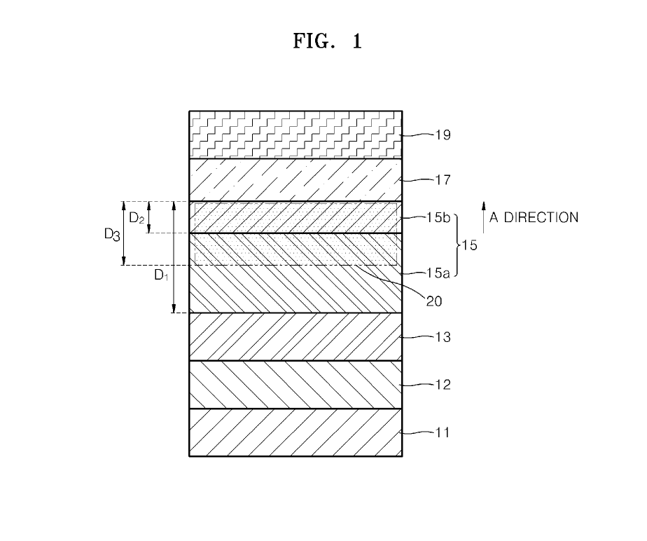

Hereinafter, an organic light-emitting diode according to an embodiment is described with reference to FIG. 1.

The organic light-emitting diode of FIG. 1 includes a substrate 11, a first electrode 12, a hole transport region 13, an emission layer 15, an electron transport region 17, and a second electrode 19, which are sequentially stacked in this stated order. The emission layer 15 includes a host and a dopant. The emission layer 15 includes a non-doping layer 15a that includes the host and does not include the dopant and a doping layer 15b that includes the host and the dopant, and the non-doping layer 15a and the doping layer 15b are sequentially stacked from the hole transport region 13.

The substrate 11, which may be any substrate that is used in general OLEDs, may be a glass substrate or a transparent plastic substrate with excellent mechanical strength, thermal stability, transparency, surface smoothness, ease of handling, and water resistance.

The first electrode 12 may be formed by depositing or sputtering a material for a first electrode on the substrate 11. When the first electrode 12 is an anode, the material for the first electrode may be selected from materials having a high work function to ease injection of holes. The first electrode 12 may be a reflection electrode, a semi-transmissible electrode, or a transmissible electrode. For use as the material for the first electrode, a transparent and highly conductive material may be used. Examples of the transparent and highly conductive material are indium tin oxide (ITO), indium zinc oxide (IZO), tin oxide (SnO₂), and zinc oxide (ZnO). The first electrode 12 may be formed as a reflective electrode using magnesium (Mg), aluminum (Al), aluminum-lithium (Al—Li), calcium (Ca), magnesium-indium (Mg—In), magnesium-silver (Mg—Ag), or the like.

The first electrode 12 may have a single-layered structure or a multi-layered structure including two or more layers. For example, the first electrode 12 may have a three-layered structure of ITO/Ag/ITO, but is not limited thereto.

The hole transport region 13 is formed on the first electrode 12. The hole transport region 13 may include at least one layer selected from a hole injection layer, a hole transport layer, a single layer having a hole injection function and a hole transport function, a buffer layer, and an electron blocking layer.

When the hole transport region 13 includes a hole injection layer, the hole injection layer may be formed on the first electrode 12 by using various methods, such as vacuum deposition, spin coating, casting, Langmuir-Blodgett (LB) deposition, or the like.

When the hole injection layer is formed using vacuum deposition, vacuum deposition conditions may vary according to the compound that is used to form the hole injection layer, and the desired structure and thermal properties of the hole injection layer to be formed. For example, vacuum deposition may be performed at a temperature of about 100° C. to about 500° C., a pressure of about 10⁻⁸ torr to about 10⁻³ torr, and a deposition rate of about 0.01 to about 100 Å/sec. However, the deposition conditions are not limited thereto.

When the hole injection layer is formed using spin coating, the coating conditions may vary according to the compound that is used to form the hole injection layer, and the desired structure and thermal properties of the hole injection layer to be formed. For example, the coating rate may be in the range of about 2000 rpm to about 5000 rpm, and a temperature at which heat treatment is performed to remove a solvent after coating may be in the range of about 80° C. to about 200° C. However, the coating conditions are not limited thereto.

For use as a hole injection material, a known hole injection material may be used, and such a known hole material may be, for example, N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylphenylamino)triphenylamine (m-MTDATA), N,N′-di(1-naphthyl)-N,N′-diphenylbenzidine (NPB), TDATA, 2-TNATA, polyaniline/dodecylbenzenesulfonic acid (pani/DBSA), poly(3,4-ethylenedioxythiophene)/poly(4-styrenesulfonate) (PEDOT/PSS), polyaniline/camphor sulfonicacid (pani/CSA), or (polyaniline)/poly(4-styrenesulfonate) (PANI/PSS), but is not limited thereto:

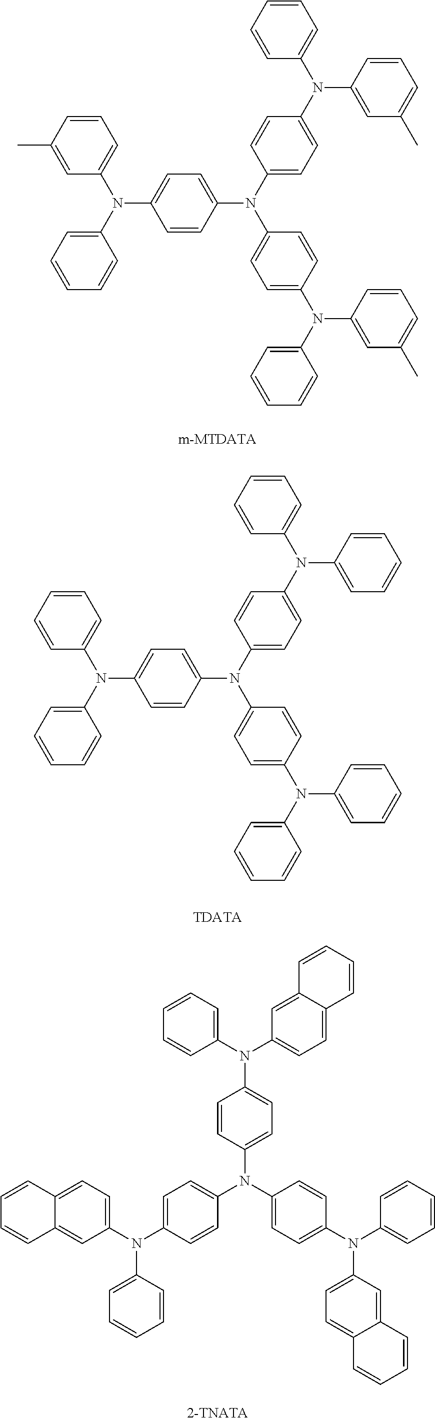

A thickness of the hole injection layer may be from about 100 Å to about 10000 Å, and in some embodiments, may be from about 100 Å to about 1000 Å. When the thickness of the hole injection layer is within this range, the hole injection layer may provide a satisfactory hole injection ability without a substantial increase in driving voltage.

The hole transport region 13 includes a hole transport layer, the hole transport layer may be formed on the first electrode 12 or the hole injection layer.

Then, the hole transport layer may be formed by using vacuum deposition, spin coating, casting, LB deposition, or the like. When the hole transport layer is formed using vacuum deposition or spin coating, the conditions for deposition and coating may be similar to those for the formation of the hole injection layer, although the conditions for deposition and coating may vary according to the material that is used to form the hole injection layer.

For use as a hole transporting material, a known hole transporting material may be used, and examples of such a known hole transporting material are a carbazole derivative, such as N-phenyl carbazole or polyvinylcarbazole, TPD, 4,4′,4″-tris(N-carbazolyl)triphenylamine (TCTA), N,N′-di 1-naphthyl)-N,N′-diphenylbenzidine (NPB), and 1,1-bis[4-[N,N′-di(p-tolyl)amino]phenyl]cyclohexane (TAPC), but are not limited thereto.

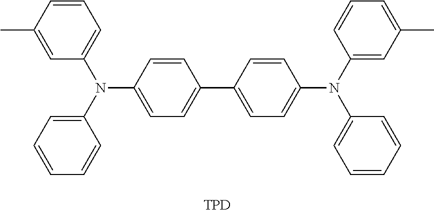

A thickness of the hole transport layer may be from about 50 Å to about 2000 Å, and in some embodiments, may be from about 100 Å to about 1500 Å. When the thickness of the hole transport layer is within this range, the hole transport layer may provide a satisfactory hole transporting ability without a substantial increase in driving voltage.

In addition, at least one of the hole injection layer and the hole transport layer may include at least one of Compounds 301 to 320 illustrated below, but is not limited thereto:

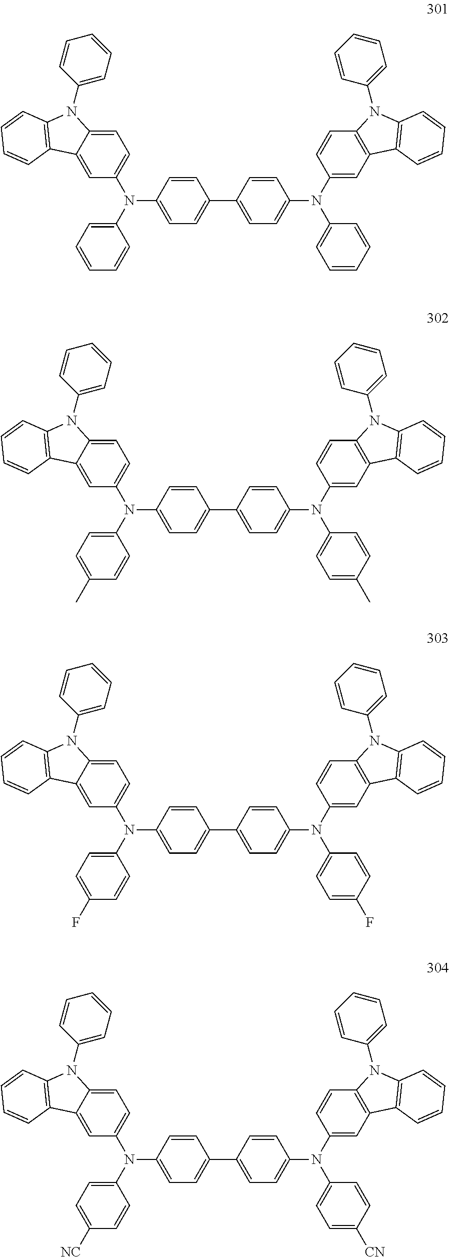 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

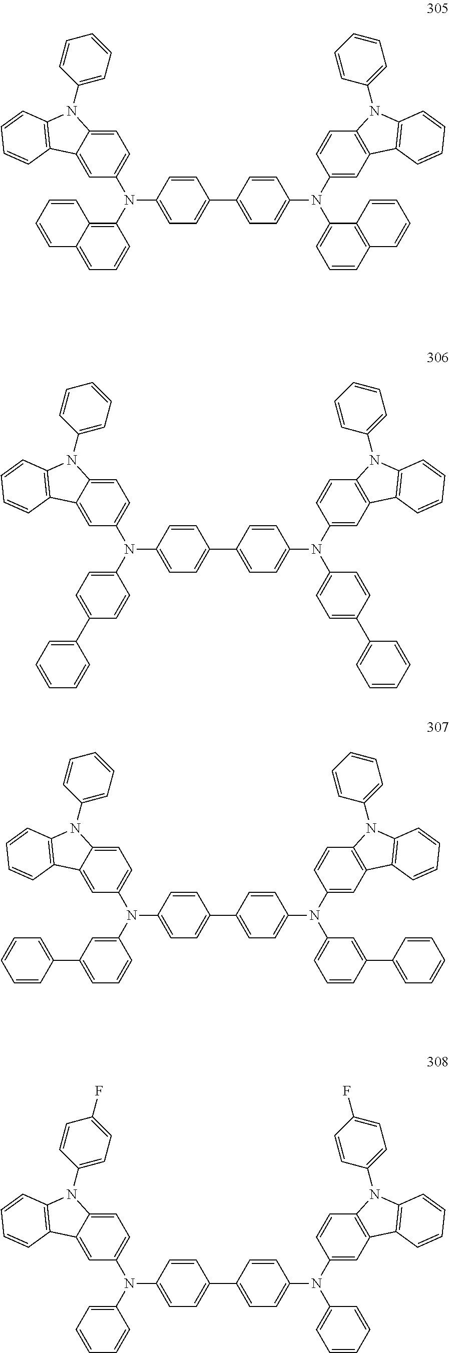 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

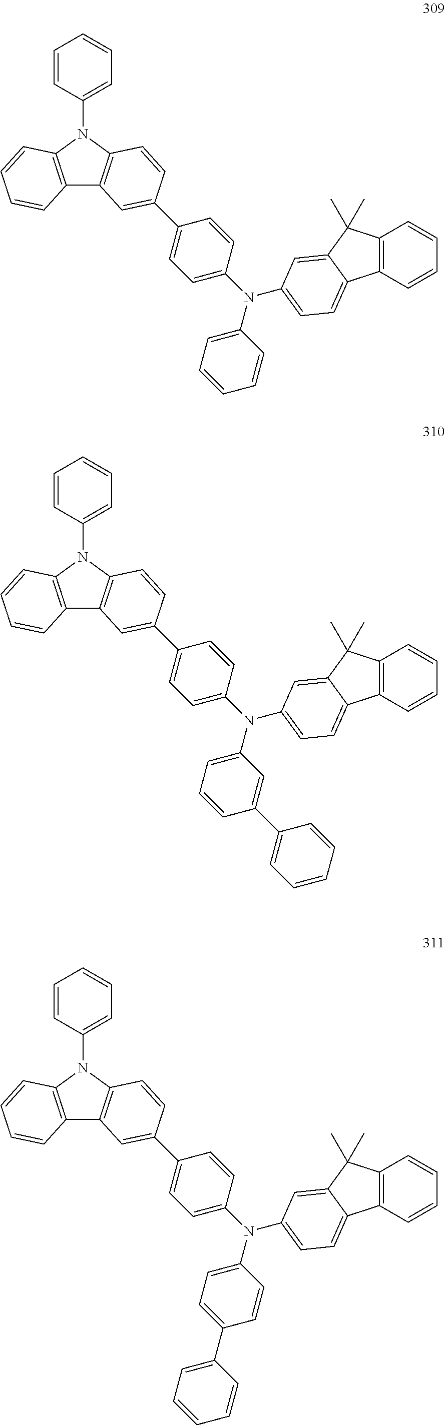 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

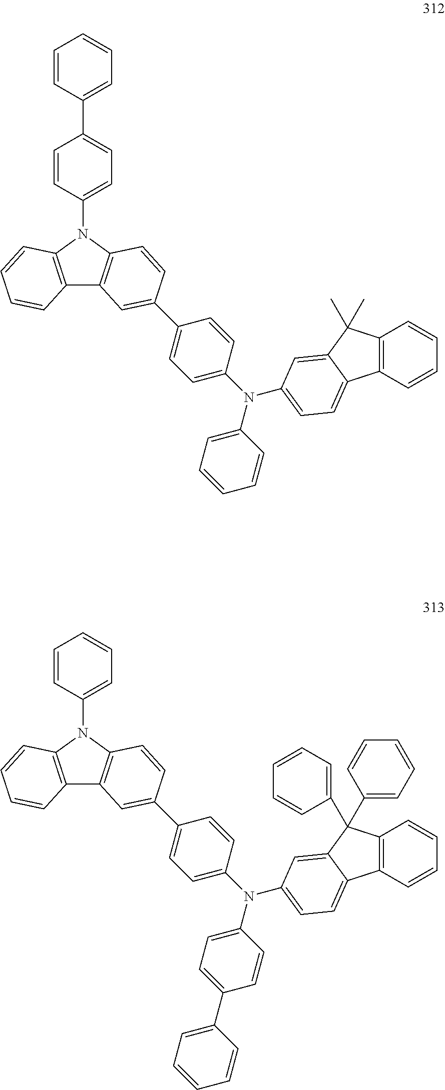 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

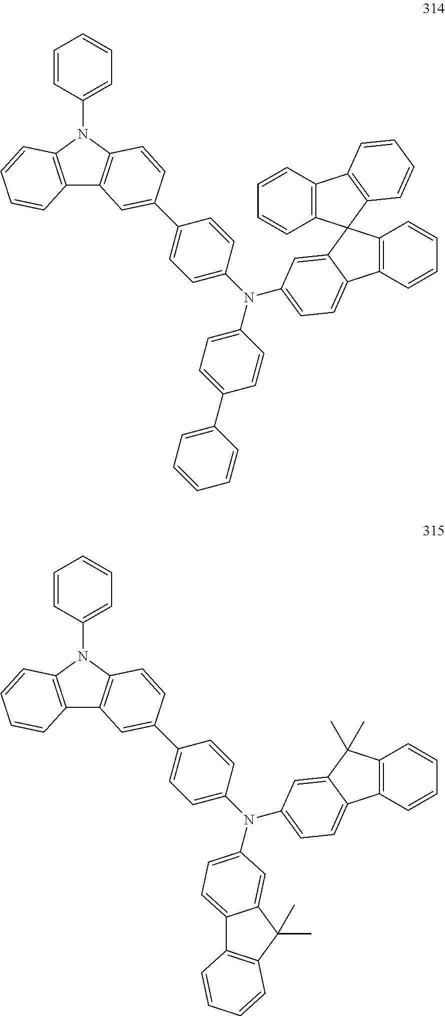 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

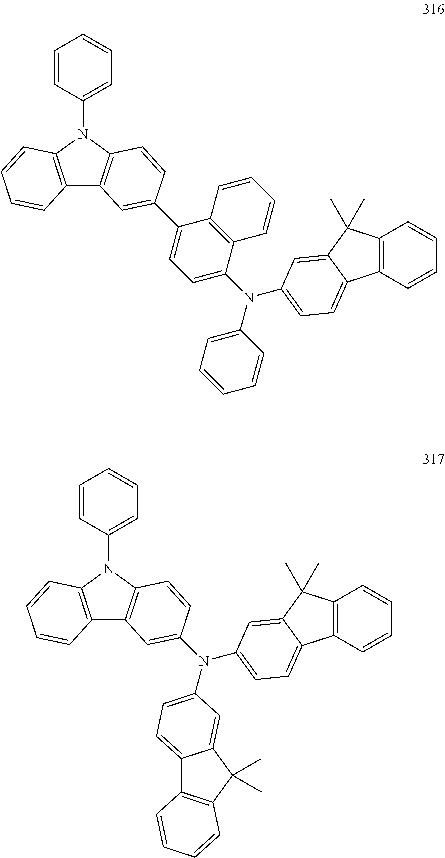 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

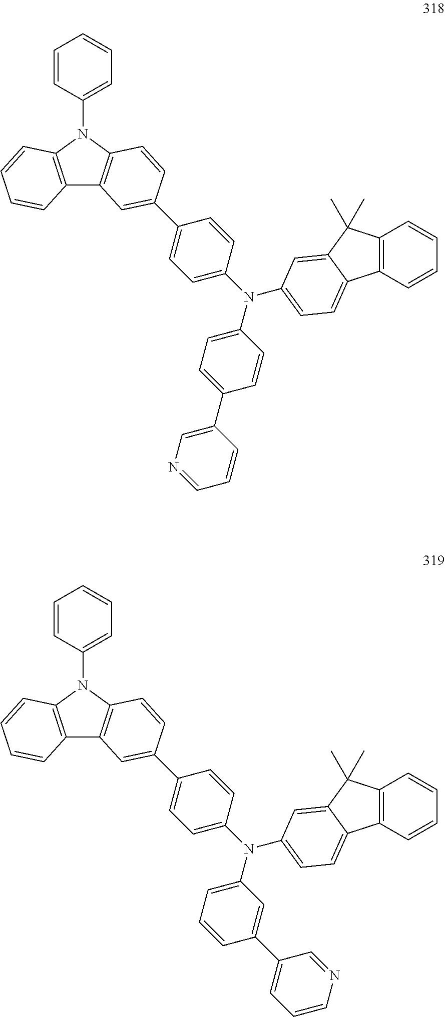 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

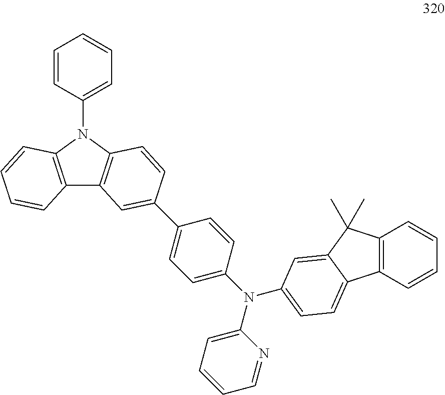 [SMILES: CC1(C)c2ccccc2-c2ccc(N(c3ccc(-c4ccc5c(c4)c4ccccc4n5-c4ccccc4)cc3)c3ccccn3)cc21]

In addition, the hole transport region 13 may include a single layer simultaneously having a hole injection function and a hole transport function. The single layer having a hole injection function and a hole transport function may include such materials for the hole injection layer or the hole transport layer described above.

The hole transport region 13 may further include a buffer layer and/or an electron blocking layer to prevent electron from entering thereinto from the electron transport region 17 for providing a resonance distance.

The hole transport region 13 may further include a charge-generating material for the improvement of conductivity and/or hole mobility.

The charge-generating material may be, for example, a p-dopant. The p-dopant may be one of quinine derivatives, metal oxides, and compounds with a cyano group, but is not limited thereto. Unlimiting examples of the p-dopant are as follows: a quinone derivative, such as tetracyanoquinonedimethane (TCNQ) or 2,3,5, 6-tetrafluoro-tetracyano-1,4-benzoquinonedimethane (F4-TCNQ); a metal oxide, such as tungsten oxide or molybdenium oxide; and a cyano group-containing compound, such as Compound 390 below, but are not limited thereto.

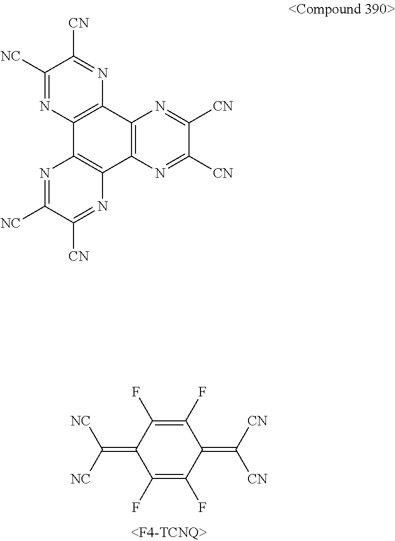 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

The charge-generating material may be uniformly or non-uniformly distributed in the hole transport region 13.

The emission layer 15 may be formed on the hole transport region 13.

The emission layer 15 includes a host and a dopant. The emission layer 15 includes the non-doping layer 15a that includes the host and does not include the dopant and the doping layer 15b that includes the host and the dopant, which are sequentially stacked in this stated order from the hole transport region 13.

The wording that “the organic light-emitting diode is driven at low gradation and/or low brightness” means that “the organic light-emitting diode is driven at a current density (J) of 0.1 mA/cm² or lower.”

When the organic light-emitting diode of FIG. 1 is driven at a current density (J) of about 0.1 mA/cm² or lower, holes arriving at the emission layer 15 from the first electrode 12 through the hole transport region 13 are combined with electrons arriving at the emission layer 15 from the second electrode 19 through the electron transport region 17 to form excitons, and in this regard, the emission layer 15 has an exciton recombination zone 20 where excitons are generated as described above and an exciton non-recombination zone (the residual of the emission layer 15 of FIG. 1 other than the dashed line region indicated by the reference numeral 20). When the organic light-emitting diode of FIG. 1 is driven at low gradation and/or low brightness, the exciton non-recombination zone and the exciton recombination zone 20 may be sequentially formed in this stated order from the hole transport region 13.

When the organic light-emitting diode is driven at low gradation and/or low brightness (for example, driven at a current density (J) of about 0.1 mA/cm² or lower), a ratio of a thickness D₃ of the exciton recombination zone 20 and a thickness D₁ of the emission layer 15 may be in a range of about 20:100 to about 100:100. Therefore, the exciton recombination zone 20 can be formed in the wide range.

In this regard, a thickness D₂ of the doping layer 15b may be smaller than the thickness D₃ of the exciton recombination zone 20.

For example, when the organic light-emitting diode is driven at low gradation and/or low brightness (for example, driven at a current density (J) of about 0.1 mA/cm² or lower), the thickness D₂ of the doping layer 15b may be in a range of about 10% to about 50% of the thickness D₃ of the exciton recombination zone 20.

According to an embodiment, a ratio of the thickness D₂ of the doping layer 15b to the thickness D₁ of the emission layer 15 may be in a range of about 1:100 to about 20:100, for example, about 5:100 to about 15:100. For example, a ratio of the thickness D₂ of the doping layer 15b to the thickness D₁ of the emission layer 15 may be 10:100.

Since the exciton recombination zone 20, which is generated when the organic light-emitting diode is driven at low gradation and/or low brightness (for example, driven at a current density (J) of about 0.1 mA/cm² or lower), is formed at the interface between the emission layer 15 and the electron transport region 17 as identified in FIG. 1, by stacking the non-doping layer 15a and the doping layer 15b as illustrated in FIG. 1 (for example, stacked in such a manner that the thickness D2 of the non-doping layer 15a satisfies such ranges), the formation of stain occurring when driving at low gradation and/or low brightness may be substantially prevented.

The formation of stain occurring when the organic light-emitting diode is driven at low gradation and/or low brightness organic light-emitting diode may be originated from high sensitivity of the organic light-emitting diode with respect to dispersion of a driving current of a thin film transistor (TFT) located under the substrate 11.

For example, when the thickness D₂ of the doping layer 15b is smaller than the thickness D₃ of the exciton recombination zone 20, which is generated when the organic light-emitting diode is driven at low gradation and/or low brightness, brightness efficiency of the organic light-emitting diode when driving at low gradation and/or low brightness may decrease. Accordingly, when driving at gradation and/or low brightness, current density is more consumed to obtain a predetermined intensity of brightness to compensate for the reduced brightness efficiency. As described above, when the organic light-emitting diode consumes relatively high current density, ultimately, sensitivity of the organic light-emitting diode with respect to a small current change of the thin film transistor (TFT) may decrease. For example, when the thickness D₂ of the doping layer 15b is designed to be smaller than the thickness D₃ of the exciton recombination zone 20, which is generated when the organic light-emitting diode is driven at low gradation and/or low brightness, and the organic light-emitting diode is driven at low gradation and/or low brightness, all the pixels of the organic light-emitting diode may substantially emit light with the same brightness regardless of a small current change of a thin film transistor, and accordingly, the formation of stain may be substantially prevented.

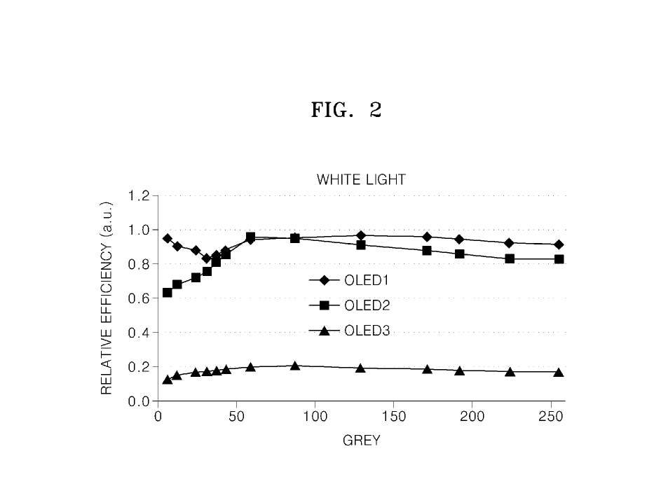

The description above may be confirmed from FIG. 2 showing gradation-efficiency graphs of organic light-emitting diodes (OLEDs) 1, 2 and 3.

First, OLEDs 1, 2 and 3 having the structures shown in Table 1 are manufactured.

TABLE 1

| | |
|---|---|
| OLED 1 | glass substrate/ITO (first electrode)/PEDOT (hole injection |
| | layer, 250 Å)/TAPC (hole transport layer, 200 Å)/mCP:Firpic |
| | (emission layer, 200 Å)/BCP (electron transport layer, |
| | 400 Å)/LiF (electron injection layer, 10 Å)/Al (second |
| | electrode) |
| | (Firpic(dopant) in the emission layer is overall uniformly |
| | doped in the emission layer) |
| OLED 2 | glass substrate/ITO (first electrode)/PEDOT (hole injection |
| | layer, 250 Å)/TAPC (hole transport layer, 200 Å)/mCP:Firpic |
| | (emission layer, 200 Å)/BCP (electron transport layer, |
| | 400 Å)/LiF (electron injection layer, 10 Å)/Al (second |
| | electrode) |
| | (Firpic(dopant) in the emission layer is doped in a depth of |
| | 20 Å (10% of the total thickness of the emission layer) |
| | from a lower portion of the electron transport layer) |
| OLED 3 | glass substrate/ITO (first electrode)/PEDOT (hole injection |
| | layer, 250 Å)/TAPC (hole transport layer, 200 Å)/mCP:Firpic |
| | (emission layer, 200 Å)/BCP (electron transport layer, |
| | 400 Å)/LiF (electron injection layer, 10 Å)/Al (second |
| | electrode) |
| | (Firpic(dopant) in the emission layer is doped in a depth of |
| | 20 Å (10% of the total thickness of the emission layer) |
| | from a upper portion of the hole transport layer) |

Referring to FIG. 2 showing gradation-efficiency graphs of OLEDs 1 to 3, only the OLED 2 having the non-doping layer 15a and the doping layer 15b illustrated in FIG. 1 showed about 30% decrease in brightness efficiency when driving at low gradation. Accordingly, in the case of only the OLED 2 having the non-doping layer 15a and the doping layer 15b illustrated in FIG. 1, the formation of stain when driving at low gradation and/or low brightness is substantially prevented.

In addition, in the case of the OLED 4 having the structure shown in Table 2, the dopant of the emission layer is doped at the interface between the electron transport layer and the emission layer and the interface between the hole transport layer and the emission layer.

TABLE 2

| | |
|---|---|
| OLED 4 | glass substrate/ITO (first electrode)/PEDOT (hole injection |
| | layer, 250 Å)/TAPC (hole transport layer, 200 Å)/mCP:Firpic |
| | (emission layer, 200 Å)/BCP (electron transport layer, |
| | 400 Å)/LiF (electron injection layer, 10 Å)/Al (second |
| | electrode) |
| | (Firpic(dopant) in the emission layer is doped in a depth of |
| | 10 Å (5% of the total thickness of the emission layer) |
| | from a lower portion of the electron transport layer, and |
| | doped in a depth of 10 Å(5% of the total thickness of |
| | the emission layer) from a upper portion of the hole |
| | transport layer) |

When the OLED 4 is driven at low gradation and/or low brightness (for example, at the current density (J) of about 0.1 mA/cm² or lower), the exciton recombination zone is formed overall in the emission layer or the exciton recombination zone is formed at the interface between the emission layer and the hole transport layer. Accordingly, the decrease in the efficiency described above may not be obtained. Thus, when driving at low gradation and/or low brightness, the formation of stain occurs.

The emission layer 15 may be formed as follows: a deposition source of the host and a deposition source of the dopant are provided in a deposition chamber, and then, a dopant outlet from among the deposition source of the dopant is closed by using a switch to deposit the host first, and then, after a predetermined period of time, the switch is separated from the dopant outlet to co-deposit the host and the dopant, thereby sequentially depositing the non-doping layer 15a and the doping layer 15b. In this regard, the dopant of the doping layer 15b of the emission layer 15 may have a concentration gradation that gradually increases toward the electron transport region 17 (indicated as A direction of FIG. 1).

The host and the dopant included in the emission layer 15 may be selected from any one of various known hosts and dopants.

Non-limiting examples of the host include Alq₃, 4,4′-N,N′-dicarbazole-biphenyl (CBP), poly(n-vinylcarbazole) (PVK), 9,10-di(naphthalene-2-yl)anthracene (ADN), 1,3,5-tris(N-phenylbenzimidazole-2-yl)benzene (TPBI), 3-tert-butyl-9,10-di-2-naphthylanthracene (TBADN), and dmCBP(see the corresponding formula below).

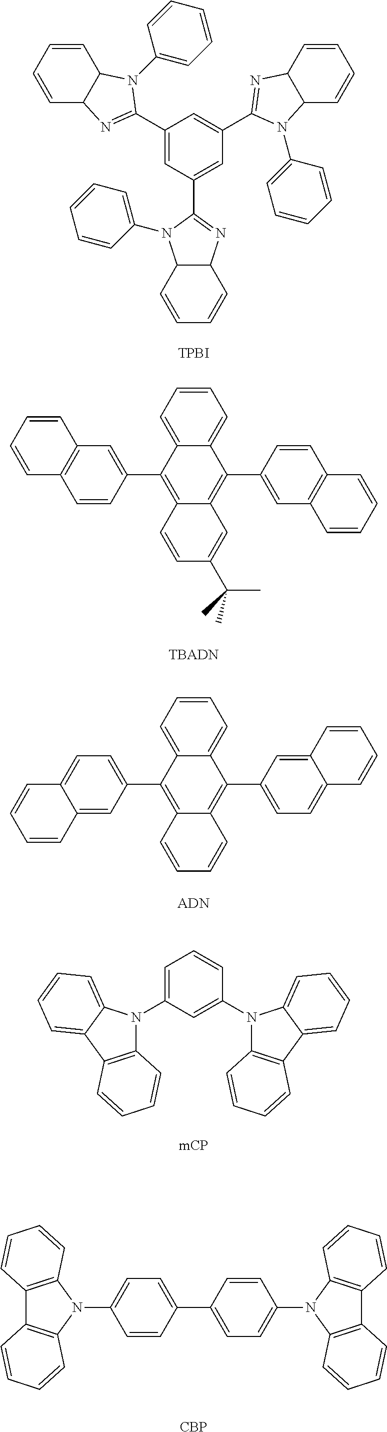

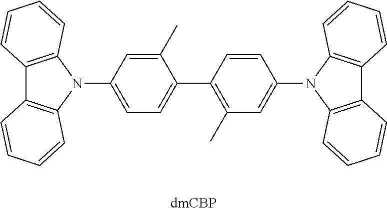 [SMILES: Cc1cc(-n2c3ccccc3c3ccccc32)ccc1-c1ccc(-n2c3ccccc3c3ccccc32)cc1C ; "dmCBP"]

The emission layer may include a blue dopant, a green dopant, and/or a red dopant.

Non-limiting examples of the blue dopant are compounds represented by the following formulae.

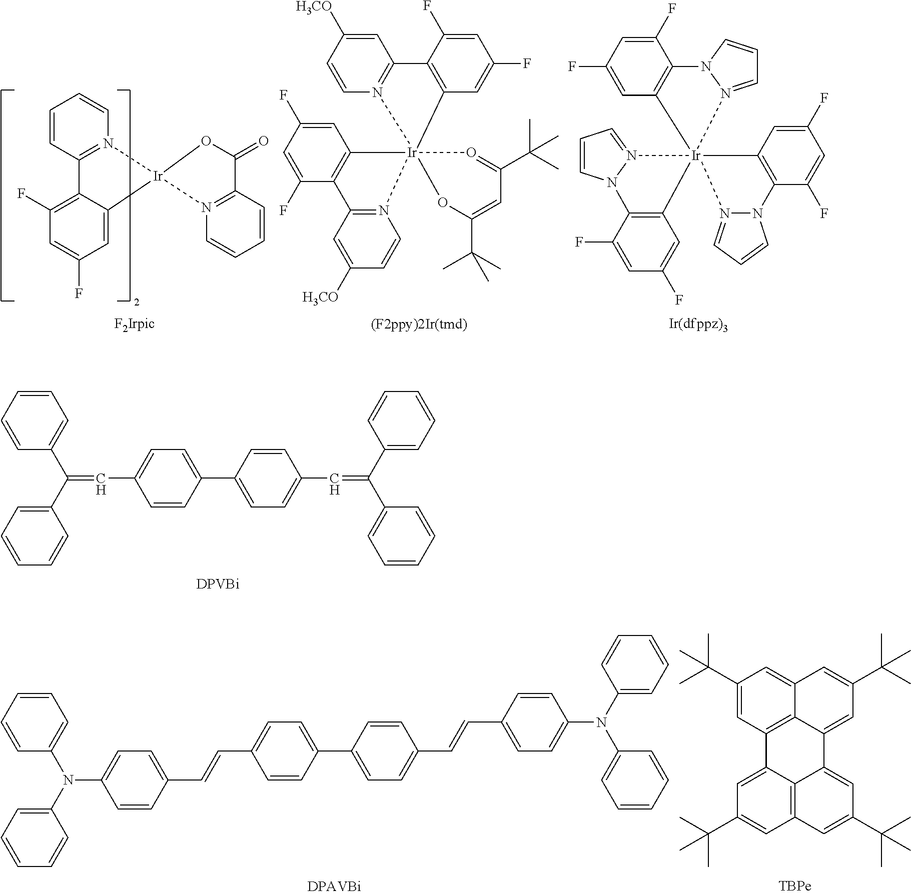

Non-limiting examples of the red dopant are compounds represented by the following formulae.

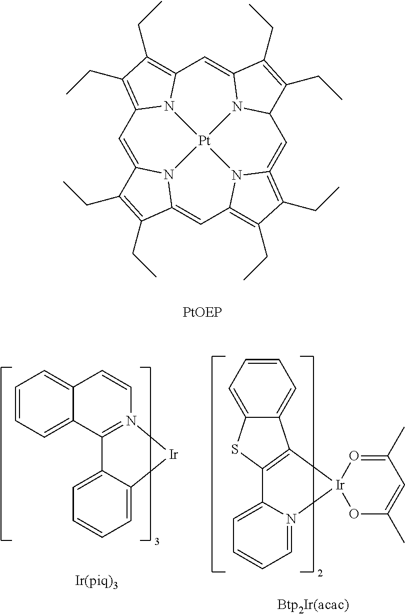

Non-limiting examples of the green dopant are compounds represented by the following formulae. As the green dopant, C545T illustrated below may be used.

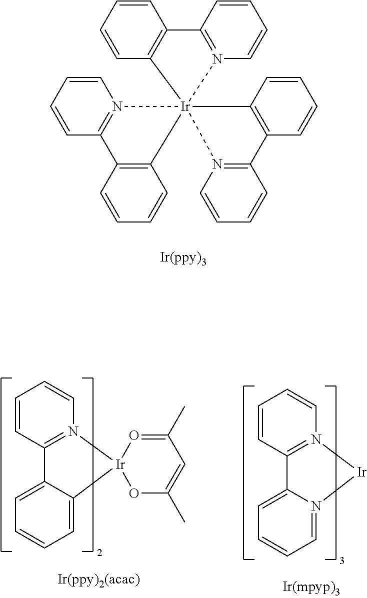

The amount of the dopant in the doping layer 15b may be from about 0.01 parts to about 15 parts by weight based on 100 parts by weight of the host. However, the amount of the dopant is not limited to this range.

A thickness D₁ of the emission layer 15 may be from about 100 Å to about 1000 Å, and in some embodiments, may be from about 200 Å to about 600 Å. When the thickness D₁ of the emission layer 15 is within these ranges, the emission layer 15 may provide improved light emitting ability without a substantial increase in driving voltage.

The electron transport region 17 is formed on the emission layer 15. The electron transport region 17 is a region through which electrons injected from the second electrode 19 pass to arrive at the emission layer 15.

The electron transport region 17 may include at least one layer selected from a hole blocking layer, an electron transport layer, an electron injection layer, and a single layer having an electron transport function and an electron injection function.

In addition, when a phosphorescent dopant is used in the emission layer, a triplet exciton or a hole may diffuse to the electron transport layer. To prevent the diffusion, a hole blocking layer may be formed by vacuum deposition, spin coating, casting, LB deposition, or the like. When the hole blocking layer is formed using vacuum deposition or spin coating, the conditions for deposition and coating may be similar to those for the formation of the hole injection layer, although the conditions for deposition and coating may vary according to the material that is used to form the hole blocking layer. Any known hole-blocking material may be used. Non-limiting examples of hole-blocking materials are oxadiazole derivatives, triazole derivatives, and phenanthroline derivatives. For example, BCP illustrated below may be used as the hole-blocking material.

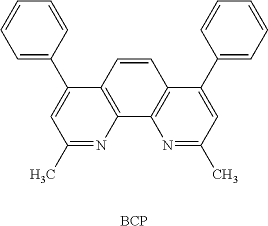 [SMILES: Cc1cc(-c2ccccc2)c2ccc3c(-c4ccccc4)cc(C)nc3c2n1 ; "BCP"]

When the electron transport region 17 includes an electron transport layer, the electron transport layer may be formed by vacuum deposition, spin coating, casting, LB deposition, or the like. When the electron transport layer is formed using vacuum deposition or spin coating, the deposition and coating conditions may be similar to those for the formation of the hole injection layer, though the deposition and coating conditions may vary according to a compound that is used to form the electron transport layer. A material for the electron transport layer may be any one of various known electron transporting materials that stably transport electrons injected from the electron injection electrode (cathode). Examples of the material for the electron transport layer are a tris(8-quinolinolate)aluminium (Alq₃), TAZ, Balq, beryllium bis(benzoquinolin-10-olate) (Bebq₂), AND, and BCP, but are not limited thereto.

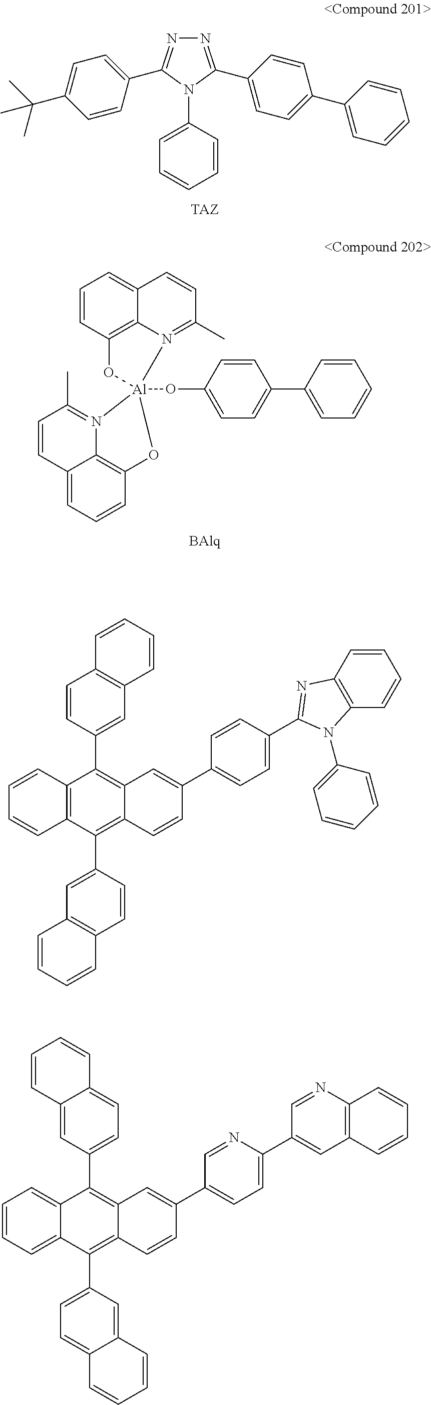

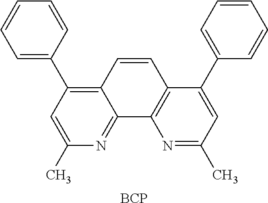

A thickness of the electron transport layer may be from about 100 Å to about 1000 Å, and in some embodiments, may be from about 150 Å to about 500 Å. When the thickness of the electron transport layer is within these ranges, the electron transport layer may have satisfactory electron transporting ability without a substantial increase in driving voltage.

The electron transport layer may further include a metal-containing material (for example, lithium quinolate), in addition to an electron transporting inorganic material.

When the electron transport region 17 includes an electron injection layer, the electron injection layer may comprise a material (for example, LiF, NaCl, CsF, Li2O, BaO, or the like) that allows electrons to be easily injected from the second electrode 19. The deposition conditions of the electron injection layer may be similar to those used to form the hole injection layer, although the deposition conditions may vary according to the material that is used to form the electron injection layer.

The thickness of the electron injection layer may be from about 1 Å to about 100 Å, and in some embodiments, may be from about 3 Å to about 90 521 . When the thickness of the electron injection layer is within these ranges, the electron injection layer may have satisfactory electron transporting ability without a substantial increase in driving voltage.

The second electrode 19 may be formed on the electron transport region 17. The second electrode 19 may be a cathode, which is an electron injection electrode. A metal for forming the second electrode may be a metal, an alloy, an electrically conductive compound, which all have a low-work function, or a mixture thereof. In this regard, the second electrode 9 may comprise lithium (Li), magnesium (Mg), aluminum (Al), aluminum (Al)-lithium (Li), calcium (Ca), magnesium (Mg)-indium (In), magnesium (Mg)-silver (Ag), or the like, and may be formed as a thin film type transmission electrode. In some embodiments, to manufacture a top-emission light-emitting diode, the transmission electrode may comprise indium tin oxide (ITO) or indium zinc oxide (IZO).

Hereinbefore, an organic light-emitting diode according to an embodiment is described with reference to FIG. 1. However, the organic light-emitting diode is not limited thereto.

By controlling a doping region of a dopant in an emission layer of an organic light-emitting diode, screen stain occurring during the organic light-emitting diode is driven at low gradation and/or low brightness is prevented.

While the present embodiments have been particularly shown and described with reference to example embodiments thereof, it will be understood by those of ordinary skill in the art that various changes in form and details may be made therein without departing from the spirit and scope of the present embodiments as defined by the following claims.

What is claimed is:

1. An organic light-emitting diode comprising:
a substrate; a first electrode on the substrate;
a second electrode facing the first electrode;
an emission layer that is interposed between the first electrode and the second electrode and comprises a host and a dopant;
a hole transport region interposed between the first electrode and the emission layer; and
an electron transport region interposed between the emission layer and the second electrode,
wherein the emission layer comprises a non-doping layer that comprises the host and does not comprise the dopant and a doping layer that comprises the host and the dopant,
wherein the non-doping layer and the doping layer are sequentially stacked.

2. The organic light-emitting diode of claim 1, wherein when the organic light-emitting diode is driven at a current density (J) of about 0.1 mA/cm² or lower, an exciton non-recombination zone and an exciton recombination zone are sequentially formed in the emission layer from the hole transport region; and
a thickness of the doping layer is smaller than a thickness of the exciton recombination zone.

3. The organic light-emitting diode of claim 2, wherein a ratio of a thickness of the exciton recombination zone to a thickness of the emission layer is in a range of about 20:100 to about 100:100.

4. The organic light-emitting diode of claim 2, wherein a thickness of the doping layer is about 10% to about 50% of the thickness of the exciton recombination zone.

5. The organic light-emitting diode of claim 1, wherein a ratio of a thickness of the doping layer to a thickness of the emission layer is in a range of about 1:100 to about 20:100.

6. The organic light-emitting diode of claim 1, wherein a ratio of a thickness of the doping layer to a thickness of the emission layer is in a range of about 5:100 to about 15:100.

7. The organic light-emitting diode of claim 1, wherein a ratio of a thickness of the doping layer to a thickness of the emission layer is about 10:100.

8. The organic light-emitting diode of claim 1, wherein the dopant of the doping layer of the emission layer has a concentration gradation that gradually increases toward the electron transport region.

9. The organic light-emitting diode of claim 1, wherein the dopant is a phosphorescent dopant or a fluorescent dopant.

10. The organic light-emitting diode of claim 1, wherein the hole transport region comprises at least one layer selected from a hole injection layer, a hole transport layer, a single layer having a hole injection function and a hole transport function, a buffer layer, and an electron blocking layer.

11. The organic light-emitting diode of claim 10, wherein the hole transport region comprises a charge-generating material.

12. The organic light-emitting diode of claim 1, wherein the electron transport region comprises at least one layer selected from a hole blocking layer, an electron transport layer, and an electron injection layer.

13. An organic light-emitting diode comprising:
a substrate; a first electrode on the substrate;
a second electrode facing the first electrode;
an emission layer that is interposed between the first electrode and the second electrode and comprises a host and a dopant;
a hole transport region interposed between the first electrode and the emission layer; and
an electron transport region interposed between the emission layer and the second electrode,
wherein the emission layer comprises a non-doping layer that comprises the host and does not comprise the dopant and a doping layer that comprises the host and the dopant,
wherein the non-doping layer and the doping layer are sequentially stacked, and
when the organic light-emitting diode is driven at a current density (J) of about 0.1 mA/cm² or lower, an exciton non-recombination zone and an exciton recombination zone are sequentially formed in the emission layer from the hole transport region; and
a thickness of the doping layer is smaller than a thickness of the exciton recombination zone.

14. The organic light-emitting diode of claim 13, wherein a ratio of a thickness of the exciton recombination zone to a thickness of the emission layer is in a range of about 20:100 to about 100:100.

15. The organic light-emitting diode of claim 13, wherein a thickness of the doping layer is about 10% to about 50% of the thickness of the exciton recombination zone.

16. The organic light-emitting diode of claim 13, wherein a ratio of a thickness of the doping layer to a thickness of the emission layer is in a range of about 1:100 to about 20:100.

17. The organic light-emitting diode of claim 13, wherein a ratio of a thickness of the doping layer to a thickness of the emission layer is in a range of about 5:100 to about 15:100.

18. The organic light-emitting diode of claim 13, wherein a ratio of a thickness of the doping layer to a thickness of the emission layer is about 10:100.

19. The organic light-emitting diode of claim 13, wherein the dopant of the doping layer of the emission layer has a concentration gradation that gradually increases toward the electron transport region.

20. The organic light-emitting diode of claim 1, wherein the dopant is a phosphorescent dopant or a fluorescent dopant.
